(19) United States
(12) Patent Application Publication
(10) Pub. No.: US 2019/0227919 A1
(43) Pub. Date: Jul. 25, 2019

(54) ELECTRONIC APPARATUS AND RECORDING MEDIUM SUITABLE FOR MANAGEMENT OF NONVOLATILE MEMORY

(71) Applicant: KYOCERA Document Solutions Inc., Osaka (JP)

(72) Inventor: Kenichiro NITTA, Osaka (JP)

(73) Assignee: KYOCERA Document Solutions Inc., Osaka (JP)

(21) Appl. No.: 16/256,808

(22) Filed: Jan. 24, 2019

(30) Foreign Application Priority Data
Jan. 24, 2018 (JP) 2018-009630

(51) Int. Cl. G06F 12/02; G11C 11/56; G06F 9/30; H01L 27/115

(52) U.S. Cl. CPC G06F 12/0238; H01L 27/115; G06F 9/3004; G11C 11/5628

(57) ABSTRACT

Provided is a electronic apparatus that determines whether or not a product guarantee period can be satisfied early and intelligently. When a write guarantee value is taken to be (Wmax), a total write amount is taken to be (Wsum), an average difference value per a unit period is taken to be (Ave.), a predicted write amount per unit period is taken to be (Wref), and a remaining guarantee period is taken to be (Dremain), a system-control unit 132 obtains the remaining guarantee period by the calculation: (Dremain)=[(Wmax)·(Wsum)]/[(Ave.)+(Wref)]; and furthermore, when an elapsed period is taken to be (Dpast), a predicted usable period is taken to be (Dprediction), obtains the predicted usable period by the calculation: (Dprediction)=(Dpast)+(Dremain); and in the case where (Dprediction)<(Dguarantee), the system-control unit 132 determines there is excessive writing.

### INCORPORATION BY REFERENCE

This application is based on and claims the benefit of priority from Japanese Patent Application No. 2018-009630 filed on Jan. 24, 2018, the contents of which are hereby incorporated by reference.

### BACKGROUND

The present disclosure relates to an electronic apparatus and a recording medium suitable for management of a nonvolatile memory.

For example, an image forming apparatus which is an MFP Multifunction Peripheral) such as a multifunctional machine or the like, is one kind of electronic apparatus. There are models of image forming apparatuses that are capable of being equipped with nonvolatile memories such as a HDD (hard disk drive), a SSD (solid state drive), a SD (secure digital card) card, a NOR Flash, a NAND Flash and the like.

Incidentally, among these nonvolatile memories, in the case of a HDD and a SSD, a self-diagnosis function called S.M.A.R.T. (Self-Monitoring, Analysis and Reporting Technology) is mounted. Moreover, in the case of a nonvolatile memory equipped with a self-diagnosis function, it is possible to acquire the write amount by using a SATA (serial advanced technology attachment) interface. This write amount indicates how many terabytes of data called TBW (Tera Byte Written) have been written.

On the other hand, in the case of a nonvolatile memory such as an SD card, NOR Flash, NAND Flash, and the like, since a self-diagnosis function called S.M.A.R.T. is not mounted, a write guarantee value called TBW cannot be acquired. In this way, in the case where it is not possible to acquire a write guarantee value, it becomes difficult to detect the life of the nonvolatile memory. In addition, when a nonvolatile memory that cannot acquire a write guarantee value reaches the end of life during use, the image forming apparatus may not be able to perform normal operation in some cases.

As a typical technique for solving such a problem, there is a data storage controller. This data storage controller, by a method of counting, counts in partition units the number of times data is written to a first nonvolatile memory having a small guarantee number indicated by the write guarantee value. When the number of times of writing partitions of a first nonvolatile memory to which data is to be written exceeds a preset number, a method of control causes data to be written to be stored in a second nonvolatile memory having a large number of times of guaranteed rewrite.

### SUMMARY

The electronic apparatus according to the present disclosure includes a nonvolatile memory, a design value management table, a difference management table, and a system-control unit. The nonvolatile memory has a plurality of storage units. The design value management table manages, as a design value, a predicted write amount for each of the storage units per a unit period based on a product guarantee period. The difference management table manages a difference between the total of the design values for each of the storage units and the total of data write amounts for each of the storage units. The system-control unit acquires the data write amount for each of the storage units in the unit period and registers the difference in the difference management table. The system-control unit acquires the total data write amount since the start of using the nonvolatile memory. The system-control unit, when a write guarantee value is taken to be (Wmax), the total write amount is taken to be (Wsum), an average value of the difference per the unit period is taken to be (Ave.), a predicted write amount per the unit period is taken to be (Wref), and a remaining guarantee period is taken to be (Dremain), obtains the remaining guarantee period by the calculation: (Dremain)=[(Wmax)−(Wsum)]/[(Ave.)+(Wref)]. Furthermore, the system-control unit, when an elapsed period is taken to be (Dpast), and a predicted usable period is taken to be (Dprediction), obtains the predicted usable period by the calculation: (Dprediction)=(Dₚₐₛₜ)+(Dremain). The system-control unit, when a guarantee period for guaranteeing the nonvolatile memory is taken to be (Dguarantee), and in the case where (Dprediction)<(Dguarantee), determines there is excessive writing.

The recording medium according to the present disclosure is a non-transitory computer-readable recording medium for storing a memory control program to be executed by a computer controlling an electronic apparatus equipped with a nonvolatile memory having a plurality of storage units. The computer, when executing the memory control program, by a design value management table, manages, as a design value, a predicted write amount for each of the storage units per a unit period based on a product guarantee period. The computer, by a difference management table, manages a difference between a total of the design values for each of the storage units and a total data write amount for each of the storage units. The computer, by a system-control unit, acquires the data write amount for each of the storage units per the unit period and registers the difference in the difference management table. Furthermore, the system-control unit acquires the total data write amount since the start of using the nonvolatile memory. The system-control unit, when a write guarantee value is taken to be (Wmax), the total write amount is taken to be (Wsum), an average value of the difference per the unit period is taken to be (Ave.), a predicted write amount per the unit period is taken to be (Wref), and a remaining guarantee period is taken to be (Dremain), obtains the remaining guarantee period by the calculation: (Dremain)=[(Wmax)−(Wsum)]/[(Ave.)+(Wref)]. Furthermore, the system-control unit, when an elapsed period is taken to be (Dpast), and a predicted usable period is taken to be (Dprediction), obtains the predicted usable period by the calculation: (Dprediction)=(Dpast)+(Dremain). The system-control unit, when a guarantee period for guaranteeing the nonvolatile memory is taken to be (Dguarantee), and in the case where (Dprediction)<(Dguarantee), determines there is excessive writing.

### BRIEF DESCRIPTION OF THE DRAWINGS

FIG. 1 is a diagram for explaining an embodiment in the case where the electronic apparatus according to the present disclosure is applied to an MFP.

FIG. 2 is a diagram for explaining an example of configuration of the SSD in FIG. 1, wherein element A illustrates the partitions of the SSD, and element B illustrates kernel management areas that manage each of the partitions.

FIG. 3A illustrates management information of the nonvolatile memory in FIG. 1, and illustrates a design value management table.

FIG. 3B illustrates management information of the nonvolatile memory in FIG. 1, and illustrates a difference management table.

FIG. 4 is a diagram for explaining an example of lifetime prediction of a nonvolatile memory on the management server side in FIG. 1.

FIG. 5 is a diagram for explaining another example of lifetime prediction of a nonvolatile memory on the management server side in FIG. 1.

FIG. 6 is a flowchart for explaining difference management and excessive writing detection in the management of the nonvolatile memory in FIG. 1.

FIG. 7 is a flowchart for explaining warning notification in management of the nonvolatile memory in FIG. 1.

### DETAILED DESCRIPTION

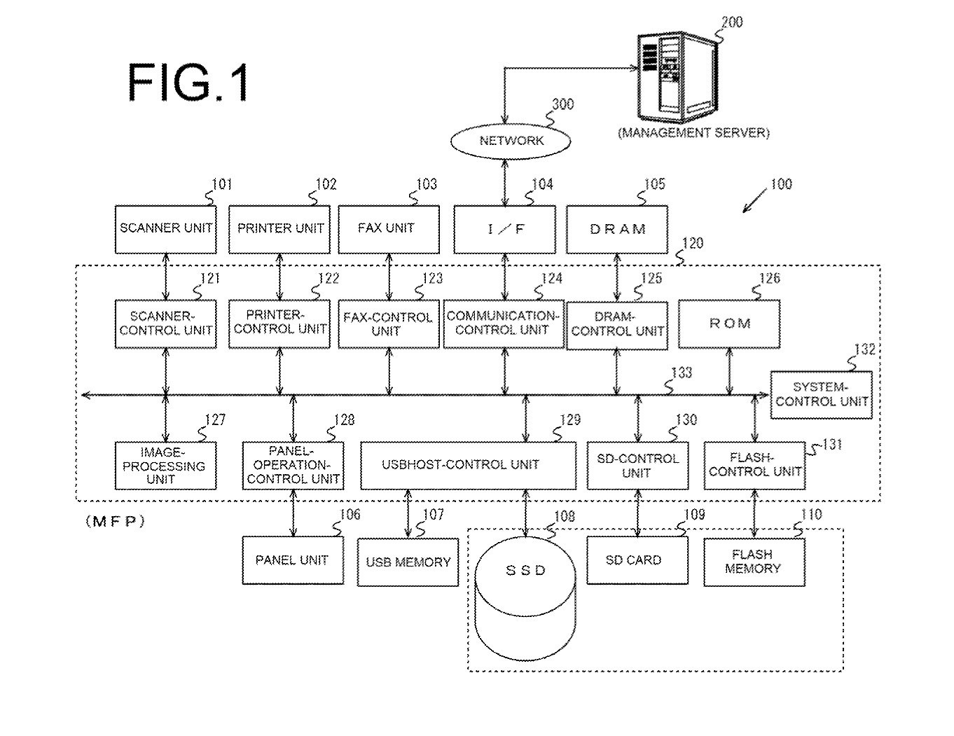

Hereinafter, an embodiment of an electronic apparatus according to the present disclosure will be described with reference to FIGS. 1 to 7. Incidentally, the example of an electronic apparatus in the following description is a MFP (multifunction peripheral), which is a complex peripheral apparatus equipped with a printing function, a copying function, a FAX function, a data transmitting/receiving function via a network, and the like.

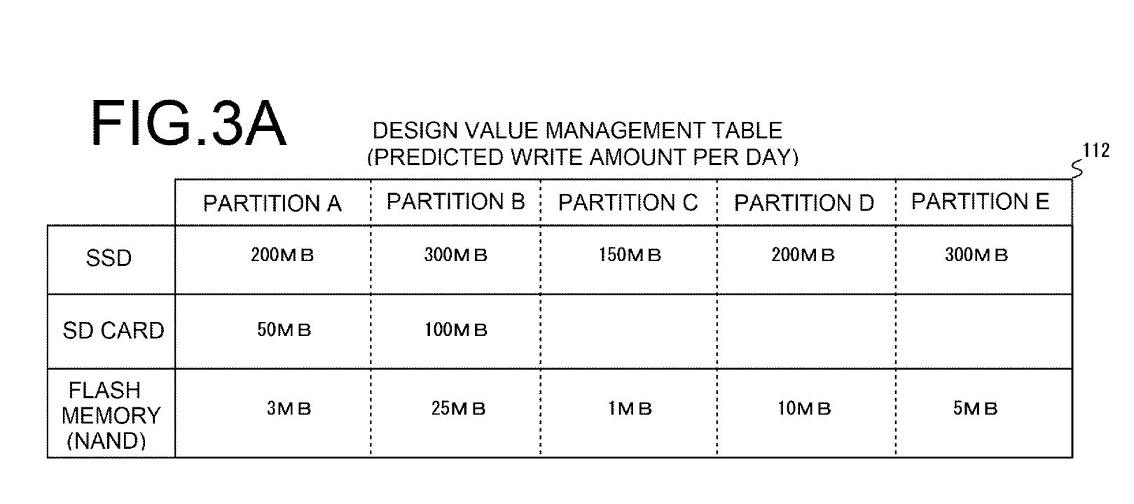

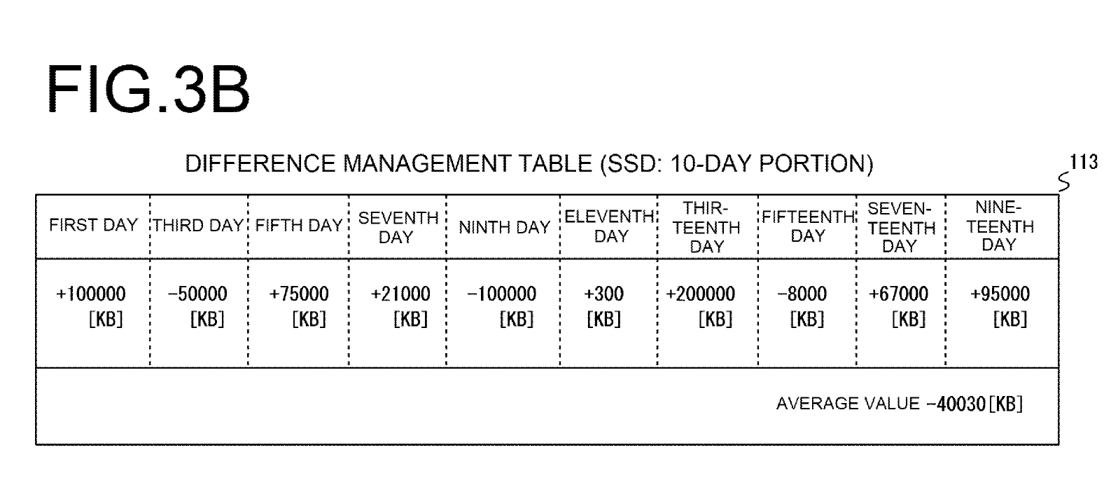

First, as illustrated in FIG. 1, the MFP 100, via a network 300 such as the Internet or an in-house LAN (Local Area Network) or the like, is connected to a management server 200 that manages the MFP 100. The management server 200 performs lifetime prediction or the like of a nonvolatile memory that cannot acquire a write guarantee value called TBW (Tera Byte Written) that indicates how many terabytes of data can be written until the end of the lifetime. This is performed based on an average write difference value (Ave.) in the difference management table 113 illustrated in FIG. 3B described later received from the MFP 100.

The MFP 100 includes a control unit 120 that controls a scanner unit 101, a printer unit 102, a FAX (facsimile) unit 103, an I/F (interface) 104, a DRAM (dynamic random access memory) 105, a panel unit 106, a USB (universal serial bus) memory 107, an SSD (solid state drive) 108, an SD card 109, and a flash memory (registered trademark) 110. Note that the USB memory 107, which is a nonvolatile memory, can be freely inserted into and removed from the main body of the MFP 100. On the other hand, the SSD 108, the SD card 109, and the Flash memory (registered trademark) 110, which are nonvolatile memories, are mounted in the main body of the MFP 100 so as not to be removable. In addition, the Flash memory (registered trademark) 110 indicates, for example, a NOR Flash, NAND Flash, or the like. Moreover, an HDD (Hard Disk Drive) may also be provided.

The scanner unit 101 is a device that converts an image of a document read by an image sensor into digital image data and inputs the image data to the control unit 120. The printer unit 102 is a device that prints an image on paper based on printing data outputted from the control unit 120. The FAX unit 103 is a device that transmits data outputted from the control unit 120 to a facsimile of another party via a telephone line and receives data from a facsimile of another party and inputs the data to the control unit 120.

The I/F 104 is a device such as a network interface card or the like. The I/F 104 is in charge of communication with the management server 200, other user terminals, content servers, web servers, and the like via a network such as an in-house LAN (local area network), the Internet or the like. The DRAM 105 is a work memory for executing a program. In addition, the DRAM 105 stores printing data and the like that has undergone image processing (rasterization) by an image-processing unit 127 described later. The panel unit 106 displays, for example, detection results of excessive writing to the SSD 108, the SD card 109, and the flash memory (registered trademark) 110 that are nonvolatile memories, and the like.

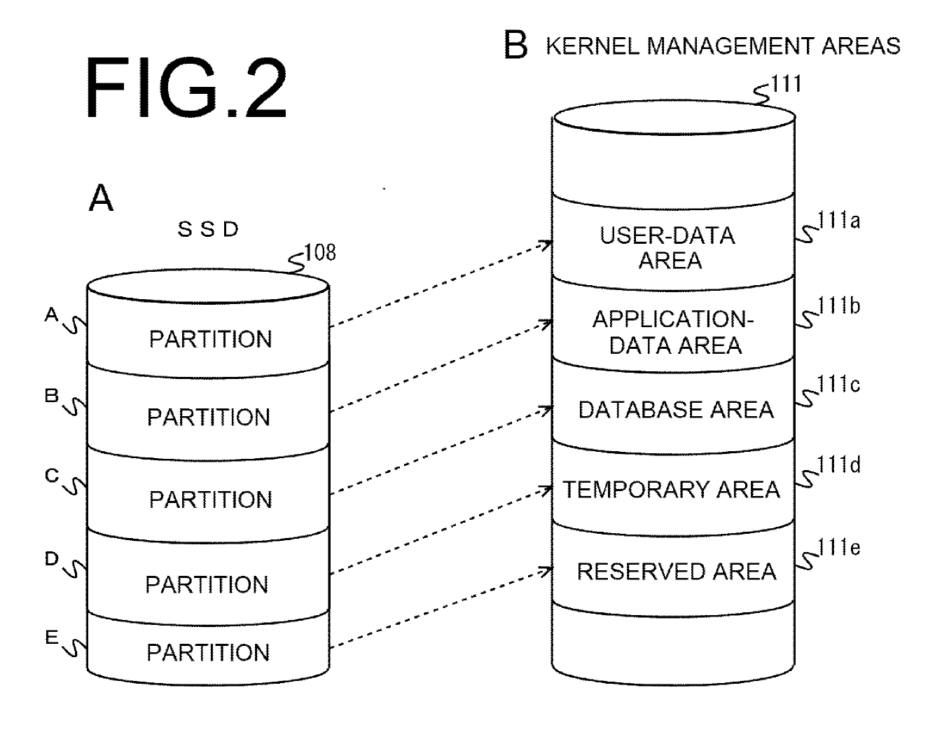

The USB memory 107 is used for registering various setting information, printing data and the like in the MFP 100. The SSD 108, the SD card 109, and the flash memory (registered trademark) 110 have partitions for storing user data, application programs (hereinafter referred to as apps) data, and the like illustrated in FIG. 2 to be described later. Incidentally, in the case of the SSD 108, a self-diagnosis function called S.M.A.R.T. (self-monitoring, analysis and reporting technology) is mounted. Moreover, in the case of a nonvolatile memory equipped with a self-diagnosis function, it is possible to acquire the write amount by using a SATA (serial advanced technology attachment) interface. This write amount indicates how many terabytes of data called TBW (tera byte written) have been written. On the other hand, in the case of the SD card 109 or Flash memory (registered trademark) 110, since the self-diagnosis function called S.M.A.R.T. is not mounted, it is not possible to acquire the write amount called TBW. However, in the present embodiment, since the SATA interface is not installed, it is not possible to acquire the TBW from the SSD 108. Therefore, the detection targets of excessive writing are the SSD 108, the SD card 109, and the flash memory (registered trademark) 110 that are nonvolatile semiconductor memories (hereinafter referred to simply as “nonvolatile memories”).

The control unit 120 is a processor that controls the overall operation of the MFP 100 by executing an image forming program, a control program, and the like. The control unit 120 includes a scanner-control unit 121, a printer-control unit 122, a FAX-control unit 123, a communication-control unit 124, a DRAM control unit 125, a ROM (read only memory) 126, an image-processing unit 127, a panel-operation-control unit 128, A USBHOST-control unit 129, an SD-control unit 130, a Flash-control unit 131, and a system-control unit 132. In addition, these units are connected to a data bus 133.

The scanner-control unit 121 controls the reading operation of the scanner unit 101. The printer-control unit 122 controls the printing operation of the printer unit 102. The FAX-control unit 123 controls the data transmitting/receiving operation by the FAX unit 103. The communication-control unit 124, via the I/F 104, controls transmitting and receiving of data and the like via a network.

The DRAM 105 is a work memory for executing a program. In addition, the DRAM 105 stores printing data and the like that has undergone image processing (rasterization) by the image-processing unit 127. The ROM 126 stores a control program for performing an operation check and the like of each unit. The image-processing unit 127 performs image processing (rasterization) on image data that is read by the scanner unit 101, for example. The panel-operation-control unit 128 controls the display operation of the panel unit 106. In addition, the panel-operation-control unit 128, via the panel unit 106, receives the start or the like of printing, copying, FAX, data transmitting/receiving via the Internet, or the like. Moreover, the system-control unit 132, for example, detects excessive writing to the SSD 108, the SD card 109, and the flash memory (registered trademark) 110 that are nonvolatile memories. Then, according to an instruction from the system-control unit 132, the panel-operation-control unit 128 displays a warning or the like notifying of a state that the product guarantee period cannot be satisfied due to the excessive writing.

The USBHOST-control unit 129 controls reading, writing and the like of data to and from the USB memory 107 and the SSD 108. The SD-control unit 130 controls reading, writing and the like of data to and from the SD card 109. The Flash-control unit 131 controls reading, writing and the like of data to and from the Flash memory (registered trademark) 110. The system-control unit 132 controls the cooperative operation and the like of each of the units. In addition, the system-control unit 132 manages a design value management table 112 illustrated in FIG. 3A and a difference management table 113 illustrated in FIG. 3B, which will be described later. The system-control unit 132, for example, detects excessive writing to the SSD 108, the SD card 109, and the flash memory (registered trademark) 110 that are nonvolatile memories. Then, the system-control unit 132, via the panel-operation-control unit 128, displays a warning or the like on the panel unit 106 notifying of a state that the product guarantee period cannot be satisfied due to the excessive writing. This will be described in detail later.

Next, the configurations of the SSD 108, the SD card 109, and the Flash memory (registered trademark) 110 will be described with reference to FIG. 2. Incidentally, in the following description, since the configurations of the SSD 108, the SD card 109, and the Flash memory (registered trademark) 110 are substantially the same, the SSD 108 will be described as a representative.

First, the SSD 108 illustrated in element A in FIG. 2 has partitions A to E as storage units. It should be noted that the number of partitions A to E is arbitrary, and is not limited to five as illustrated in the drawing. The kernel management areas 111 illustrated in element B of FIG. 2 are managed by the system-control unit 132, and indicate areas for managing the partitions A to E of the SSD 108. In other words, the system-control unit 132 executes a mounting process for each of the partitions A to E. The system-control unit 132, for example, manages the partition A as a user-data area 111a, manages the partition B as an application-data area 111b, manages the partition C as a database area 111c, manages the partition D as a temporary area 111d, and manages the partition E as a reserved area 111e. Incidentally, the partition E of the SSD 108 managed as the reserved area 111e is used, for example, as an alternative write area when excessive writing occurs in any of the partitions A to D.

Next, referring to FIGS. 3A and 3B, tables of the SSD 108, the SD card 109, and the Flash memory (registered trademark) 110 managed by the system-control unit 132 will be described. Note that in the following description, it is presumed that the SSD 108 has partitions A to E, the SD card 109 has partitions A to B, and the Flash memory (registered trademark) 110 has partitions A to E.

First, FIG. 3A illustrates an example of a design value management table 112 of the SSD 108, the SD card 109, and the Flash memory (registered trademark) 110. The design value management table 112 is stored in the USB memory 107 and the SSD 108. The design value management table 112 manages design values that indicate a predicted write amount in a unit period (one day in this embodiment) based on the number of years of the product guarantee (for example, 5 years) as the product guarantee period of the SSD 108, the SD card 109, and the Flash memory (registered trademark) 110. In other words, in the case of the SSD 108, the design values are managed with partition A set to 200 MB, partition B set to 300 MB, partition C set to 150 MB, partition D set to 200 MB, and partition E set to 300 MB. In the case of the SD card 109, the design values are managed with partition A set to 50 MB and partition B set to 100 MB. In the case of the Flash memory (registered trademark) 110, the design values are managed with partition A set to 3 MB, partition B set to 25 MB, partition C set to 1 MB, partition D set to 10 MB, and partition E set to 5 MB. Note that the unit period is not limited to the number of days and can be arbitrarily changed. Moreover, the design value of each partition is not limited to the amount illustrated in FIG. 3A and can be arbitrarily changed.

Next, FIG. 3B illustrates an example of the difference management table 113 that manages the average value of the difference amounts with respect to the design values of the entire 10-day partitions A to E for the SSD 108, for example. The difference management table 113 is stored in the USB memory 107 and the SSD 108. The difference management table 113 manages the difference between the total of the data write amounts in the respective partitions A to E and the total of the design values of the respective partitions A to E and the average value per unit period (one day) of the difference. In other words, the amount of data written to the SSD 108 is acquired every two days (that is, every other day) from the start of system startup as the power to the MFP 100 is turned ON, for example. That is, the amount of data to be written on the first day is acquired the day after the system startup date, and then acquired every other day thereafter. Incidentally, the system-management unit 132 stores the write amount at the time of the occurrence of writing data to each of the partitions A to E in the USB memory 107 and the SSD 108, and accumulates and manages write data amounts for each of the partitions A to E during the unit period.

Acquisition of the average value per unit period (one day) of the difference with respect to the design values of the entire partitions A to E is executed, for example, at the time when there is acquisition of the data write amount for a specified number of times (in this embodiment, 10 times (10 days)). In addition, acquisition of the average value per unit period of the difference may be performed for each period of an integral multiple of the unit period, but it is necessary to perform acquisition at least every period corresponding to the specified number of times. Moreover, the specified number of times is not limited to 10 times (10 days), but can be arbitrarily changed. Particularly, depending on the usage situation, the amount of data written in any one of the partitions A to E may temporarily indicate a value higher than the design value. In this case, by increasing the number of times of the acquisition of the average value from 10 times (10 days) to 20 times (20 days), it is possible to avoid the effect of the temporarily increased data write amount. In addition, the interval (acquisition interval) for acquiring the data write amount is not limited to every two days (every other day), and can be arbitrarily changed. Moreover, acquisition of the data write amount may be performed every day without any interval. Furthermore, the timing for starting acquisition of the data write amount is not limited to the system startup accompanying power-ON, but may be based on the system time of the MFP 100.

Here, the difference management table 113 illustrates a case where the average value of the total of the difference amounts for 10 days is −40030 [KB]. In this way, in the case where the average value becomes negative, the system-control unit 132 determines that the number of product guarantee years will be satisfied. On the other hand, in the case where the average value is positive, the system-control unit 132 determines that there is excessive writing. In that case, it is predicted that a state will occur in which the number of product guarantee years will not be satisfied.

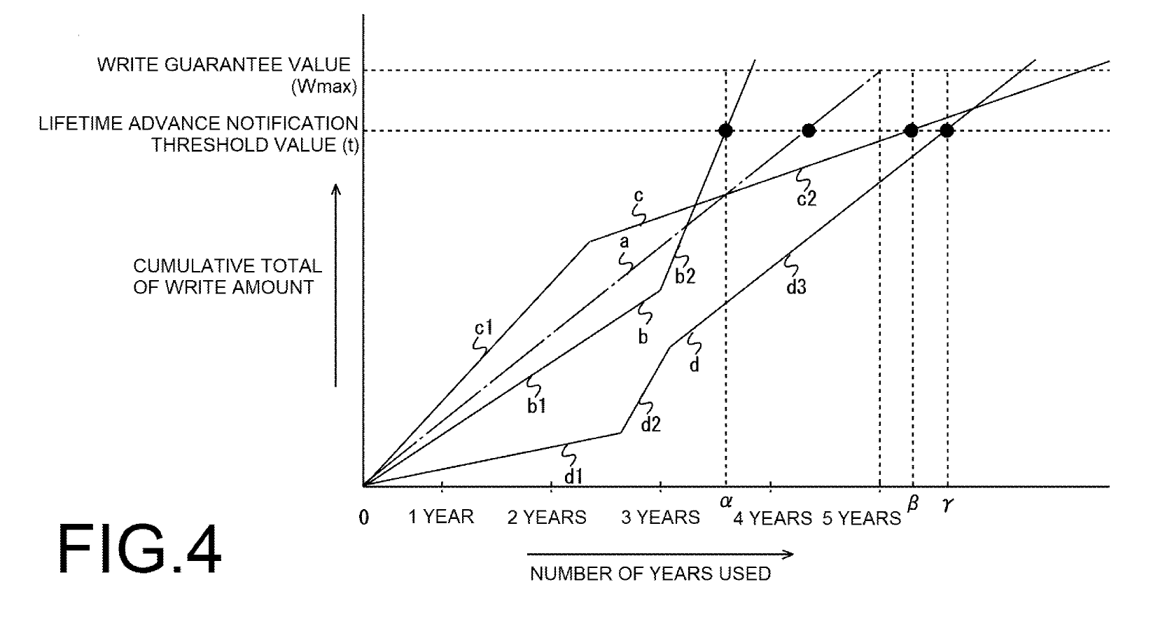

Next, FIG. 4 illustrates an example of lifetime prediction of nonvolatile memory by the management server 200 managing the MFP 100. In other words, FIG. 4 illustrates the cumulative value of total of the write amounts to each of the partitions A to E obtained from the MFP 100, that is, the transition of the total write amount of data from the start of writing (that is, the start of use) of the nonvolatile memory. It should be noted that the system-management unit 132 updates the total of the data write amount based on the total of the data write amount to each of the partitions A to E and the acquisition interval of the data write amount, and stores the total data write amount in the USB memory 107 and the SSD 108. Updating of the total data write amount may be executed at least at the timing of acquiring the average value per unit period of the difference with respect to the design values of the partitions A to E as a whole.

In addition, in FIG. 4, the straight line a indicates a transition in guaranteeing the number of product guarantee years (for example, 5 years). In the case where the average value indicated in the difference management table 113 in FIG. 3B is zero or transitions in a negative direction, it indicates that the number of product guarantee years (for example, 5 years) is guaranteed.

On the other hand, polygonal line b indicates a transition of predicting a state in which it will not be possible to satisfy the number of product guarantee years (for example, 5 years). In other words, when the average value indicated in the difference management table 113 of FIG. 3B transitions in a negative direction, the transition is like a straight line b1, and midway when the average value transitions in a positive direction, the transition is like a straight line b2 and it is predicted that a state will occur in which the number of product guarantee years (for example, five years) cannot be satisfied.

However, polygonal lines c and d indicate a transition of predicting a state in which it will be possible to satisfy the number of product guarantee years (for example, 5 years). In other words, in the case where the average value indicated by the difference management table 113 in FIG. 3B transitions in a positive direction, the polygonal line c becomes a transition like the straight line c1, and midway when the average value transitions in a negative direction, the polygonal line c becomes a transition like the straight line c2, and a state is predicted in which it will be possible to satisfy the number of product guarantee years (for example, 5 years). In addition, the polygonal line d indicates a transition like the straight line d1 when the average value indicated in the difference management table 113 of FIG. 3B transitions in a negative direction, and midway transitions as a straight line d2 when the average value transitions in a positive direction. When the average value further transitions midway in a negative direction, and transitions like the straight line d3, a state will be predicted in which it will be possible to satisfy the number of product guarantee years (for example, 5 years).

Here, depending on the usage situation of the nonvolatile memory, the writing state may change as in the polygonal lines b, c, d. Particularly, when the average value transitions in a positive direction midway like polygonal line b, a state may occur in which it is not possible to satisfy the number of product guarantee years (for example, 5 years). Although details will be described later, in this case, as will be described later, the system-control unit 132 obtains the number of predicted usable days (Dprediction). Then, the obtained predicted number of usable days (Dprediction) is compared with the guaranteed number of days guaranteed for the nonvolatile memory (Dguarantee), and in the case where (Dprediction)<(Dguarantee), it is determined that there is excessive writing.

Incidentally, in the case of determining whether or not excessive writing is performed, the system-control unit 132 performs the following calculation. In other words, the system-control unit 132 sets the write guarantee value to (Wmax), the total write amount to (Wsum), the average of the differences to (Ave.), the predicted write amount per day to (Wref), and the remaining guarantee days to (Dremain). In this case, the remaining guarantee days is obtained by the calculation: (Dremain)=[(Wmax)−(Wsum)]/[(Ave.)+(Wref)]. Furthermore, the system-control unit 132 obtains the number of predicted usable days by the calculation: (Dprediction)=(Dpast)+(Dremain), where the number of elapsed days is taken to be (Dpast) and the number of predicted usable days is taken to be (Dprediction). In addition, when the number of guarantee days guaranteed for the nonvolatile memory is taken to be (Dguarantee), the system-control unit 132 determines that excessive writing is performed when (Dprediction)<(Dguarantee). More specifically, excessive writing is determined during the periods of the straight lines b2, c1, and d2.

However, even in the case where the system-control unit 132 determines excessive writing, the total amount of data to be written is still small, and there is a possibility of satisfying the number of product guarantee days depending on the future use situation. In this case, in a state in which the total write amount (Wsum) exceeds a lifetime advance notification threshold value (t) on the basis of a lifetime advance notification threshold value (t) that is smaller by a preset value than the write guarantee value (Wmax), a case where excessive writing is determined will be described. In this case, the system-control unit 132 issues with a first warning notification that it is highly probable that the number of guarantee days (Dguarantee) cannot be satisfied. This first warning notification is issued when the transition exceeds the lifetime advance notification threshold value (t) before the number of product guarantee years (for example, 5 years), as indicated by the broken line b. In this case, the first warning notification for informing that there is a high possibility that the number of guarantee days (Dguarantee) cannot be satisfied is displayed on the panel unit 106 or issued to the management server 200.

On the other hand, in a state in which the total write amount (Wsum) exceeds the lifetime advance notification threshold (t) on the basis of a lifetime advance notice threshold (t) that is smaller than the write guarantee value (Wmax) by a preset value, a case where excessive writing is not determined will be described. In this case, the system-control unit 132 issues a second warning notification that the number of guarantee days (Dguarantee) can be satisfied, but that the replacement of the nonvolatile memory is near. This second warning notification is issued when the transition exceeds the lifetime advance notification threshold value (t) after the number of product guarantee years (for example, 5 years), such as in the case of the polygonal lines c and d. In this case, the second warning notification informing that the number of guarantee days (Dguarantee) can be satisfied, but that the replacement of the nonvolatile memory is near is displayed on the panel unit 106 or issued to the management server 200.

Here, as the lifetime advance notification threshold value (t), before the nonvolatile memory stops working due to its lifetime being reached, it is desirable that the value be the number of days in which an appropriate response concerning replacement of the nonvolatile memory, and the like by a developer, sales company, service personnel or the like can be received. In addition, it is preferable that a margin of a certain number of days be given for the response related to replacement or the like of the nonvolatile memory by a developer, sales company, service personnel, or the like. In this case, the lifetime advance notification threshold value (t) can be set to, for example, 30 days before the write guarantee value (Wmax). Here, for example, 30 days before the write guarantee value (Wmax) can be the number of days based on the transition guaranteeing the number of product guarantee years (for example, 5 years) indicated by the straight line a.

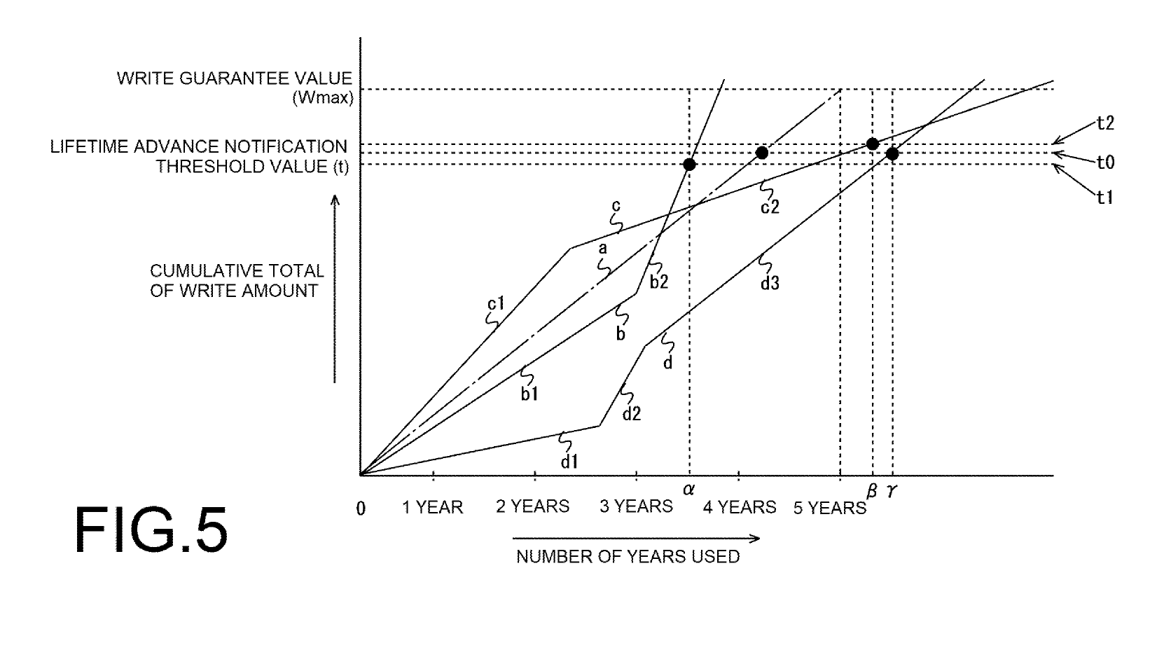

Incidentally, as can be seen from polygonal lines b, c, and d in FIG. 4, the respective slopes are different because the respective average write difference values (Ave.) are different before and after exceeding the lifetime advance notification threshold value (t). In this case, as illustrated in FIG. 4, in the case where a common lifetime advance notification threshold value (t) is provided for each polygonal line b, c, d, and depending on the slope of polygonal lines b, c, d, there occurs a case where the write guarantee value (Wmax) will be reached within 30 days, and a case where the write guarantee value (Wmax) is reached after 30 days. Particularly, in the case where the write guarantee value (Wmax) will be reached within 30 days, there may be cases where the margin of the number of days for dealing with replacement of the nonvolatile memory or the like by a developer, a sales company, service personnel, or the like may be lost. In this case, as illustrated in FIG. 5 described later, when a lifetime advance notification threshold value (t) corresponding to each slope is provided for each of the polygonal lines b, c, and d, it is possible to prevent a reduction or the like in the margin of the number of days for dealing with replacement of nonvolatile memory or the like by a developer, sales company, service personnel, or the like.

FIG. 5 illustrates another example of a case where lifetime advance notification threshold values (t) corresponding to the respective slopes are provided for each of the polygonal lines b, c, and d for predicting the lifetime of the nonvolatile memory by the management server 200 that manages the MFP 100. In other words, as illustrated in FIG. 5, the value of the lifetime advance notification threshold value (t) for the straight line a indicating a transition guaranteeing the number of product guarantee years (for example, 5 years) is set to t0, and this value to is used as a reference. Here, in the case of polygonal line b, since the slope becomes large like the straight line b2, the value of the lifetime advance notification threshold value (t) is set to t1 that is smaller than t0. Moreover, in the case of polygonal line c, since the slope becomes small like the straight line c2, the value of the lifetime advance notification threshold value (t) is set to t2 that is larger than t0. Furthermore, in the case of polygonal line d, since the slope is mostly the same as the straight line a as illustrated by the straight line d3, the value of the lifetime advance notification threshold value (t) is set to t0. By determining each of the values t0, t1, and t2 of the lifetime advance notification threshold value (t) on the basis of the straight line a indicating a transition that guarantees the number of product guarantee years (for example, 5 years), the difference in the slopes with respect to the straight line a can be obtained.

In addition, as the timing for obtaining the respective values t0, t1, and t2 of the lifetime advance notification threshold value (t), the number of remaining guarantee days (Dremain) is first obtained from the transition of the respective polygonal lines b, c, d. When the number of remaining guarantee days (Dremain) reaches a specific period, for example, 60 days, the average write difference value (Ave.), which is the average of the write differences for 10 days, is changed to a shortened average obtained by averaging the write differences over a period reduced from 10 days, for example, to 3 days. Furthermore, lifetime advance notification threshold values (t) indicated by t0 to t1 are set for the respective polygonal lines b, c and d based on the positive or negative difference of the shortened average value for the straight line a indicating a transition that guarantees the number of product guarantee years (for example, 5 years). As a result, it is possible to set the lifetime advance notification threshold values (t) according to the use situation of the nonvolatile memory, which is the respective slope of each of polygonal lines b, c, and d, so it is possible to prevent a reduction or the like in the margin of the number of days for dealing with replacement or the like of nonvolatile memory by a developer, a sales company, service personnel, or the like.

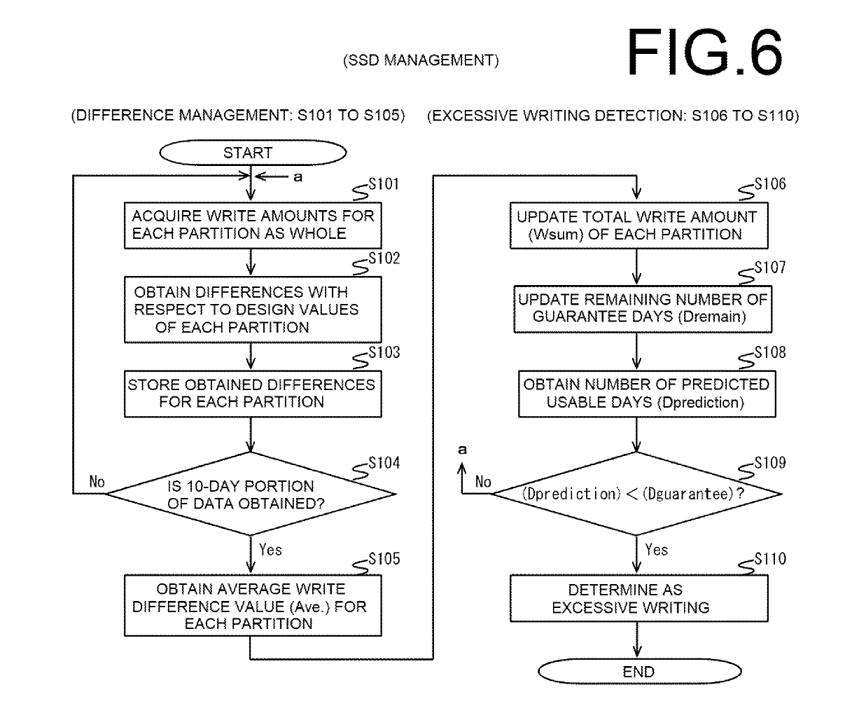

Next, management of the nonvolatile memory will be described with reference to FIG. 6. In the following description, the configurations of the SSD 108, the SD card 109, and the Flash memory (registered trademark) 110 that are nonvolatile memories are substantially the same, so the SSD 108 will be described as a representative. Moreover, it is presumed that the design values that define the predicted write amount per day of each partition A to E of the SSD 108 are managed by the design value management table 112 in FIG. 3A. Furthermore, the following steps S101 to S105 indicate the procedure of difference management, and the steps S106 to S110 indicate the procedure of excessive writing detection.

### (Step S101)

The system-control unit 132 acquires the write amount of each partition A to E of the SSD 108.

In this case, the system-control unit 132 acquires the write amount of the data written in each of the partitions A to E of the SSD 108 via the USBHOST-control unit 129.

### (Step S102)

The system-control unit 132 obtains differences with respect to the design values of each of the partitions A to E as a whole of the SSD 108.

In this case, the system-control unit 132 acquires a write amount of each partition A to E of the SSD 108 on the first day, for example. Then, the system-control unit 132 compares the total of the design values of the respective partitions A to E of the SSD 108 indicated by the design value management table 112 in FIG. 3A with the total of the obtained write amounts of each of the partitions A to E of the SSD 108, and obtains the difference between the total of the design values and the total of the write amounts.

### (Step S103)

The system-control unit 132 stores the obtained difference.

In this case, the system-control unit 132 registers the obtained difference in the difference management table 113 in FIG. 3B.

### (Step S104)

The system-control unit 132 determines whether or not 10 days of data has been obtained.

In this case, the system-control unit 132 references the difference management table 113 in FIG. 3B and determines that data for 10 days cannot be obtained unless the difference for 10 days has been registered (step S104: NO), the process returns to step S101.

On the other hand, the system-control unit 132 references the difference management table 113 in FIG. 3B and determines that data for 10 days has been obtained when the difference for 10 days has been registered (step S104: YES), the process then moves to step S105.

### (Step S105)

The system-control unit 132 obtains the average write difference value (Ave.) of each of the partitions A to E of the SSD 108.

In this case, the system-control unit 132 references the difference management table 113 in FIG. 3B, obtains the average write difference value (Ave.) for 10 days, and registers it in the difference management table 113.

### (Step S106)

The system-control unit 132 updates the total write amount (Wsum) of each partition A to E.

In this case, the system-control unit 132 adds the total write amount of each partition A to E for 10 days to the total write amount (Wsum) from the start of writing, and acquires the latest total write amount (Wsum).

### (Step S107)

The system-control unit 132 updates the number of remaining guarantee days (Dremain).

In this case, the system-control unit 132 obtains the number of remaining guarantee days (Dremain) by the calculation: Number of remaining guarantee days (Dremain)=[Write guarantee value (Wmax)−Total write amount (Wsum)]/[Average write difference value (Ave.)+Predicted write amount per day (Wref)].

### (Step S108)

The system-control unit 132 obtains the number of predicted usable days (Dprediction).

In this case, the system-control unit 132 obtains the number of predicted usable days (Dprediction) by the calculation: Number of predicted usable days (Dprediction)=Number of elapsed days (Dpast)+Number of remaining guarantee days (Dremain).

### (Step S109)

The system-control unit 132 determines whether or not the number of predicted usable days (Dprediction)<number of guarantee days (Dguarantee).

In this case, the system-control unit 132 obtains the number of guarantee days (Dguarantee) by the calculation: Number of guarantee days (Dguarantee)=365 days×5 years.

Then, the case will be described in which the number of predicted usable days (Dprediction) obtained by the system-control unit 132 in step S108 is greater than the number of guarantee days (Dguarantee). In this case, the system-control unit 132 determines that the condition: Number of predicted usable days (Dprediction)<Number of guarantee days (Dguarantee) is not satisfied (step S109: NO), and the process moves to step S101.

On the other hand, the case will be described in which the number of predicted usable days (Dprediction) obtained by the system-control unit 132 in step S108 is less than the number of guarantee days (Dguarantee). In this case, the system-control unit 132 determines that the number of predicted usable days (Dprediction)<number of guarantee days (Dguarantee) (step S109: YES), and the process moves to step S110.

### (Step S110)

The system-control unit 132 determines that there is excessive writing.

In this case, the system-control unit 132 determines that there is excessive writing because the number of predicted usable days (Dprediction) does not satisfy the number of guarantee days (Dguarantee).

In this case, the system-control unit 132 may cause the panel-operation-control unit 128 to display contents indicating excessive writing and the like on the panel unit 106.

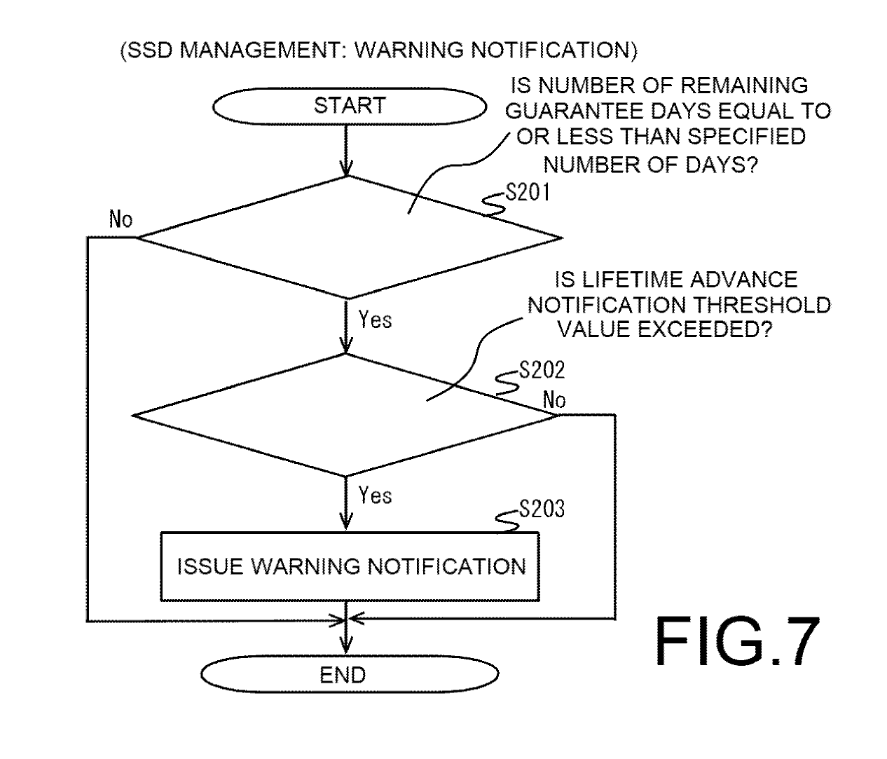

Next, a warning notification in management of the nonvolatile memory will be described with reference to FIG. 7.

### (Step S201)

The system-control unit 132 determines whether or not the number of remaining guarantee days (Dremain) is equal to or less than a specified number of days.

In this case, even in the case where the system-control unit 132 determines in step S110 in FIG. 6 that there is excessive writing, there is a possibility that the total write amount (Wsum) is small and that, depending on the future use situation, the number of guarantee days (Dguarantee) may be satisfied.

Therefore, the system-control unit 132 obtains the number of remaining guarantee days (Dremain) by the calculation: Number of remaining guarantee days (Dremain)=[Write guarantee value (Wmax)−Total write amount (Wsum)]/[Average write difference value (Ave.)+Predicted write amount per day (Wref)].

Moreover, when the obtained number of remaining guarantee days (Dremain) is not equal to or less than 50 days, for example, the system-control unit 132 determines that the number of remaining guarantee days (Dremain) is not equal to or less than a specified number of days (step S201: NO), and terminates the process.

However, when the obtained number of remaining guarantee days (Dremain) is equal to or less than 50 days, for example, the system-control unit 132 determines that the number of remaining guarantee days (Dremain) is equal to or less than a specified number of days (step S201: YES), and the process moves to step S202.

### (Step S202)

The system-control unit 132 determines whether or not the lifetime advance notification threshold value (t) is exceeded.

In this case, the system-control unit 132 obtains the number of predicted usable days (Dprediction) by the calculation: Number of predicted usable days (Dprediction)=Number of elapsed days (Dpast)+Number of remaining guarantee days (Dremain).

Then, when the number of predicted usable days (Dprediction) does not exceed the lifetime advance notification threshold value (t), for example, 30 days, the system-control unit 132 determines that the lifetime advance notification threshold value (t) is not exceeded (step S202: NO), and terminates the process.

However, when the number of predicted usable days (Dprediction) does exceed the lifetime advance notification threshold value (t), for example, 30 days, the system-control unit 132 determines that the lifetime advance notification threshold value (t) is exceeded (step S202: YES), and the process moves to step S203.

### (Step S203)

The system-control unit 132 issues a warning notification.

In this case, when there is a transition such as in the case of the polygonal line b in FIG. 4, for example, when the lifetime advance notification threshold value (t) will be exceeded before the number of product guarantee years (for example, 5 years), the system-control unit 132 issues a first warning notification. The first warning notification notifies that there is a high possibility that the number of guarantee days (Dguarantee) cannot be satisfied. Incidentally, the first warning notification is displayed on the panel unit 106 or issued to the management server 200.

In addition, when there is a transition such as in the case of the polygonal lines c and d in FIG. 4, for example, when the lifetime advance notification threshold value (t) will be exceeded after the number of product guarantee years (for example, 5 years), the system-control unit 132 issues a second warning notification. The second warning notification notifies that the replacement of the nonvolatile memory is near although the number of guarantee days (Dguarantee) can be satisfied. Incidentally, the second warning notification is displayed on the panel unit 106 or issued to the management server 200.

As described above, in the present embodiment, the design value management table 112 manages the predicted write amount for each storage unit per unit period based on the product guarantee period as the design value, the difference management table 113 manages the difference between the total of the design values for each storage unit and the total data write amounts for each storage unit, and the system-control unit 132 acquires the data write amount for each storage unit in a unit period and registers the difference in the difference management table 113. Moreover, when the write guarantee value is taken to be (Wmax), the total write amount is taken to be (Wsum), the average difference value is taken to be (Ave.), the predicted write amount per day is taken to be (Wref), and the number of remaining guarantee days is taken to be (Dremain), the system-control unit 132 obtains the number of remaining guarantee days by the calculation: (Dremain)=[(Wmax)−(Wsum)]/[(Ave.)+(Wref)]; and furthermore, when the number of elapsed days is taken to be (Dpast), and the number of predicted usable days is taken to be (Dprediction), the system-control unit 132 obtains the number of predicted usable days by the calculation: (Dprediction)=(Dpast)+(Dremain); and when the number of guarantee days for guaranteeing the nonvolatile memory is taken to be (Dguarantee), and in the case where (Dprediction)<(Dguarantee), the system-control unit 132 determines there is excessive writing.

As a result, in the case where the number of predicted usable days (Dprediction) does not satisfy the number of guarantee days (Dguarantee), excessive writing can be determined, so it is possible to determine early and intelligently whether or not the product guarantee period can be satisfied.

In the data-storage controller according to the above-described typical technique, the number of times that data is written to a first nonvolatile memory having a small number of guaranteed rewrites is counted in partition units. Since data is written to a second nonvolatile memory having a large number of guaranteed rewrites before the first nonvolatile memory reaches the end of life, data reliability can be secured.

Incidentally, the lifetime of a nonvolatile memory such as an SD card, NOR Flash, NAND Flash or the like can be predicted to some extent depending on the number of product guarantee years. However, the lifetime of the nonvolatile memory varies depending on usage conditions such as the number of times of data rewrite, data write amount, data write interval, and the like.

Therefore, when the lifetime of a first nonvolatile memory is detected only by the number of times of writing to the partitions of the first nonvolatile memory such as in the case of the data storage controller of the typical technique, the lifetime of the first nonvolatile memory cannot be detected before the number of times of writing exceeds a specific number. In this way, there is a problem in that when it is not possible to detect the lifetime of the first nonvolatile memory before the number of times of writing exceeds the specific number of times, it is not possible to predict early a state in which the number of product guarantee years cannot be satisfied.

With the electronic apparatus and the recording medium according to the present disclosure, in the case where the predicted usable period (Dprediction) is less than the guarantee period (Dguarantee), excessive writing can be determined, so it is possible to determine early and intelligently whether or not the product guarantee period can be satisfied.

Incidentally, in the present embodiment, the storage unit of the nonvolatile memory is taken to be a partition, however it may be a memory cell constituting the nonvolatile memory. In that case, “partition” may be replaced with “memory cell”, and this embodiment may be applied accordingly.

It should be noted that in the explanation of the present embodiment, an MFP 100 is used as the electronic apparatus, however the embodiment is not limited to this example and may be applied to other electronic apparatuses such as a multifunction printer, a PC (Personal Computer), and the like.

What is claimed is:

1. An electronic apparatus comprising:
a nonvolatile memory having a plurality of storage units;
a design value management table that manages, as a design value, a predicted write amount for each of the storage units per a unit period based on a product guarantee period;
a difference management table for managing a difference between the total of the design values for each of the storage units and the total of data write amounts for each of the storage units; and
a system-control unit that acquires the data write amount for each of the storage units in the unit period and registers the difference in the difference management table; wherein
the system-control unit
acquires the total data write amount since the start of writing to the nonvolatile memory;
when a write guarantee value is taken to be (Wmax), the total write amount is taken to be (Wsum), an average value of the difference per the unit period is taken to be (Ave.), a predicted write amount per the unit period is taken to be (Wref), and a remaining guarantee period is taken to be (Dremain), obtains the remaining guarantee period by the calculation:
(Dremain)=[(Wmax)−(Wsum)]/[(Ave.)+(Wref)];
furthermore, when an elapsed period is taken to be (Dpast), and a predicted usable period is taken to be (Dprediction), obtains the predicted usable period by the calculation:
(Dprediction)=(Dpast)+(Dremain); and
when a guarantee period for guaranteeing the nonvolatile memory is taken to be (Dguarantee), and
in the case where (Dprediction)<(Dguarantee),
determines there is excessive writing.

2. The electronic apparatus according to claim 1, wherein
a lifetime advance notification threshold value that is smaller than the write guarantee value by a preset value is provided; and
in a case where the system-control unit determines there is excessive writing in a state in which the total write amount exceeds the lifetime advance notification threshold value, the system-control unit issues a first warning notification notifying that there is a high possibility that the guarantee period cannot be satisfied.

3. The electronic apparatus according to claim 2, wherein
in a case where the system-control unit determines there is not excessive writing in a state in which the total write amount exceeds the lifetime advance notification threshold value, the system-control unit issues a second warning notification notifying that the guarantee period can be satisfied, however, replacement of the nonvolatile memory is near.

4. A recording medium that is a non-transitory computer-readable recording medium for storing a memory control program to be executed by a computer controlling an electronic apparatus equipped with a nonvolatile memory having a plurality of storage units; and the computer, when executing the memory control program:
by a design value management table, manages, as a design value, a predicted write amount for each of the storage units per a unit period based on a product guarantee period;
by a difference management table, manages a difference between a total of the design values for each of the storage units and a total data write amount for each of the storage units;
by a system-control unit, acquires the data write amount for each of the storage units per the unit period and registers the difference in the difference management table; and furthermore
the system-control unit
acquires the total data write amount since the start of using the nonvolatile memory;
when a write guarantee value is taken to be (Wmax), the total write amount is taken to be (Wsum), an average value of the difference per the unit period is taken to be (Ave.), a predicted write amount per the unit period is taken to be (Wref), and a remaining guarantee period is taken to be (Dremain), obtains the remaining guarantee period by the calculation:
(Dremain)=[(Wmax)−(Wsum)]/[(Ave.)+(Wref)];
furthermore, when an elapsed period is taken to be (Dpast), and a predicted usable period is taken to be (Dprediction), obtains the predicted usable period by the calculation:
(Dprediction)=(Dpast)+(Dremain); and
when a guarantee period for guaranteeing the nonvolatile memory is taken to be (Dguarantee), and
in the case where (Dprediction)<(Dguarantee),
determines there is excessive writing.
